(19) United States
(12) Patent Application Publication
(10) Pub. No.: US 2007/0090360 A1
(43) Pub. Date: Apr. 26, 2007

(54) Blanket implant diode

(75) Inventors: Sheng-Huei Dai, Hsinchu (TW); Ya-Chin King, Hsinchu (TW); Chun-Jen Huang, Taipei (TW); L.C. Kao, Taipei (TW)

Correspondence Address: MCKEE, VOORHEES & SEASE, P.L.C., 801 GRAND AVENUE, SUITE 3200, DES MOINES, IA, 50309-2721, US

(73) Assignee: Vishay General SemiConductors, LLC, Hauppauge, NY (US)

(21) Appl. No.: 11/415,522

(22) Filed: May 2, 2006

Related U.S. Application Data
(60) Provisional application No. 60/728,713, filed on Oct. 20, 2005.

(51) Int. Cl. H01L 29/04; H01L 21/00; H01L 29/15; H01L 29/10; H01L 31/00; H01L 31/036

(52) U.S. Cl. 257/59; 438/28; 257/72

(57) ABSTRACT

Blanket implant diode which can be used for transient voltage suppression having a P+ substrate implanted with an N-type dopant blanket implant near a top surface of the substrate, creating a P− region. An oxide mask is layered adjacent to and above the P− region. The oxide mask is partially etched away from a portion of the P− region, creating an etched region. An N-type main function implant is implanted into the etched region, creating an N+ region above the P+ substrate and adjacent the P− region. And, a metal is layered above the oxide mask in the etched region to form an electrode. Terminations may be attached electrically to both sides of the P-N junction. Methods of making and using the present invention and methods for transient voltage suppression are also provided.

### CROSS-REFERENCE TO RELATED APPLICATIONS

This application claims priority under 35 U.S.C. § 119 of a provisional application Ser. No. 60/728,713 filed Oct. 20, 2005, which application is hereby incorporated by reference in its entirety.

### BACKGROUND OF THE INVENTION

The present invention relates to low voltage transient voltage suppressors and similar devices. Specifically, the present invention relates to blanket implant diodes.

Reverse biased diodes are commonly used as transient voltage suppressors. The breakdown voltage value of these devices is usually in a range of 6 volts to 450 volts. These suppressing devices have advantages of simple structure and manufacturing process, low leakage current under normal bias, and sharp I-V transition at breakdown conditions.

As technology advances, supply voltage for CMOS devices is getting lower. Breakdown voltage of diodes can be reduced by raising the doping concentration on both sides of the P-N junction. However, the raised doping concentration will lead to shallower junction and larger curvature junction edge. The electric field at the large curvature area will be enhanced. Due to enhanced electric field at the junction edge, the edge will break down earlier than the main junction. In addition, the current crowding effect will result in larger resistance and smoother I-V characteristics. Both of these two phenomena are bad for transient voltage suppressor applications. Therefore, it is desirable to have an improved low voltage transient voltage suppressor.

In view of the forgoing, a primary feature or advantage of the present invention is to provide an improved blanket implant diode.

Another feature or advantage of the present invention is to provide a low voltage and very low voltage transient voltage suppression device.

Another feature or advantage of the present invention is to provide a diode which uses a one-mask process to reduce cost of the diode.

Another feature or advantage of the present invention is a diode which can be processed or manufactured with a reduced processing cycle time.

A further feature or advantage of the present invention is a diode with reduced doping concentration of starting wafer and the electrical field at the P-N junction corner edge.

A further feature or advantage of the present invention is a diode with reduced corner electrical e-field of P-N junction.

A further feature or advantage of the present invention is a diode with electrical field crowding at the edge for low voltage transient voltage suppression.

A further feature or advantage of the present invention is the provision of a blanket implant diode which is economical to manufacture, durable in use and efficient in operation.

A still further feature or advantage of the present invention is a method of transient voltage suppression using an improved voltage suppression device.

One or more of these and/or other features or advantages of the present invention will be apparent from the specification and claims that follow.

### BRIEF SUMMARY OF THE INVENTION

One or more of the foregoing features or advantages may be achieved by a blanket implant diode having a P+ substrate implanted with an N-type dopant blanket implant near a top surface of the substrate, creating a P− region. An oxide mask is layered adjacent to and above the P− region. The oxide mask is partially etched away from a portion of the P− region, creating an etched region. An N-type main junction implant is implanted into the etched region creating an N+ region above the P+ substrate and adjacent the P− region. Finally, a metal is layered above the oxide mask and the etched region.

One or more of the foregoing features or advantages may also be achieved by creating a diode by implanting an N-type dopant blanket implant near the top surface of a P+ substrate, thereby creating a P− region, layering an oxide mask adjacent to and above the P− region, etching away a portion of the mask, thereby creating an etched region, implanting an N-type main junction implant into the P− region of the etched region creating an N+ region above the P+ substrate and adjacent the P− region, and layering a metal above the oxide mask in the etched region.

One or more of the foregoing features or advantages may additionally be achieved by a transient voltage suppression device having a P+ substrate implanted with an N-type dopant blanket implant near a top surface of the substrate creating a P− region. An oxide mask is layered adjacent to and above the P− region. The oxide mask is partially etched away from a portion of the P− region, creating an etched region. An N-type main junction implant is implanted into the etched region creating an N+ region above the P+ substrate and adjacent the P− region. A metal electrode is then layered above the oxide mask and the etched region. A first connector termination is electrically connected to the metal electrode and a second connector termination is electrically connected to the substrate.

One or more of the foregoing features or advantages may additionally be achieved by creating a transient voltage suppression device by electrically connecting a first connector termination of a voltage suppressing device to an electrical circuit between a first point in the electrical circuit with a transient voltage is expected to be. The voltage suppressing device has a P+ substrate implanted with an N-type dopant blanket implant near a top surface of the substrate creating a P− region. An oxide mask is layered adjacent to and above the P− region. The oxide mask is partially etched away from a portion of the P− region, creating an etched region. An N-type main junction implant is implanted into the etched region creating an N+ region above the P+ substrate and adjacent the P− region. A metal electrode is layered above the oxide mask in the etched region. The first connector termination is electrically connected to the metal electrode and a second connector termination is electrically connected to the substrate. The second connector termination is electrically connected to a second point in the electrical circuit where a transient voltage is expected to be.

### BRIEF DESCRIPTION OF THE FIGURES AND DRAWINGS

FIGS. 1-6 show one embodiment of the present invention in the various stages of production.

FIGS. 7 and 8 show simulated results for one embodiment of a blanket implant diode device.

FIGS. 9 and 10 show simulated results for one embodiment of a junction termination extension (JTE) structure diode device.

FIGS. 11 and 12 show simulated results for one embodiment of a no modification diode device.

FIG. 13 shows a table with simulated peak electrical field at the main junction for the three types of structures of a diode device.

FIG. 14 shows a normalized edge electrical field versus depth simulation for three type structures of diode devices.

### DETAILED DESCRIPTION OF THE PREFERRED EMBODIMENT

This invention relates to a blanket implant diode and method of manufacture and use. The present invention uses a blanket implant to reduce the doping concentration of a starting wafer and the electrical field at the P-N junction corner edge. The field of technology is ion implantation technology and termination design. The present invention also addresses problems, issues or needs in the area of implant dosage and energy.

In high doping concentration P-N junction products, such as low voltage transient voltage suppression (TVS), the major breakdown current follows the band-to-band-tunneling equation:
1_{BR}˜G^{BB}=A.BTBT·(E²/EG^{1/2})·exp(−B.BTBT·(Eg^{3/2}/E))
(A.BTBT, B.BTBT, and Eg are all constants)

The breakdown current highly depends on the electrical field. Under normal biased voltage, the electrical field at the corner is generally larger than the main junction. In other words, the corner is the major leakage source under normal biased voltage. When the corner electrical field is suppressed, the leakage current can be reduced. Therefore, the present invention suppresses the corner electrical field to reduce leakage current.

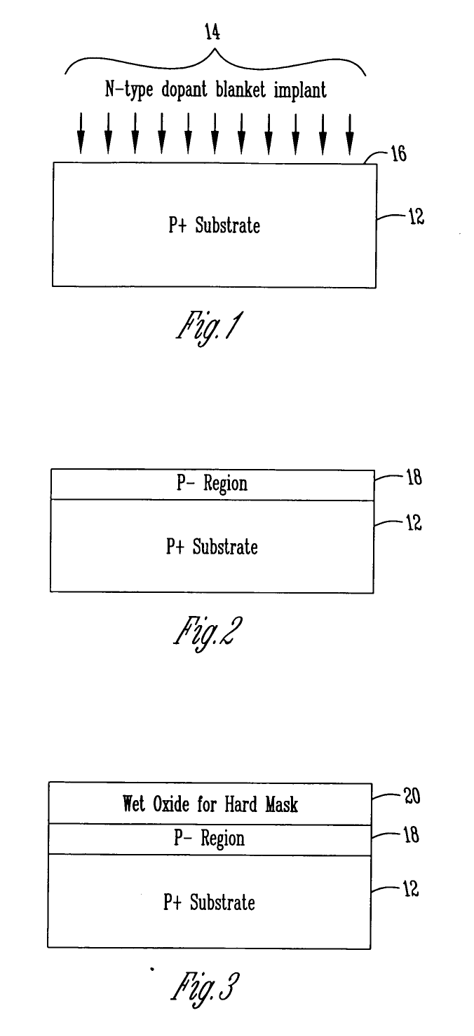

Referring now to FIGS. 1-6, a P-N junction diode 10 can be constructed by beginning with a P+ substrate 12. Preferably the P+ substrate 12 is approximately 0.001˜0.01 Ω-CM boron doped wafer. Then, an N-type dopant blanket implant 14 is implanted to the top surface 16 of the P+ substrate 12. The blanket implant device preferably undergoes about an 80 Kev, 1·10¹²˜1·10¹⁵ cm⁻², arsenic implantation and drive-in in this step, while a conventional P-N device does not.

The blanket implant 14 creates a P− region 18 in the upper area of the P+ substrate 12. A wet oxide mask 20 is used for implantation hard mask above the P− region 18. One photo-mask is used to define a main implantation area. A standard etching procedure is used to form an etched region 22 in the oxide 20 above the P− region 18. Then, an N-type main junction implant 24 is implanted into the P− region 18. The N-type main junction implant 24 is preferably an about 80 Kev, 1·10¹⁵˜1·10¹⁷ cm⁻² arsenic implant and drive-in to form the main junction implantation 24. This forms an N+ region 26 above the P+ substrate and adjacent the P− regions 18. Then, a deposit metal 28 is deposited in the etched region 22 to form an electrode. Additionally, the side of the P+ substrate opposite the metal 28 can be polished and a deposit metal 30 is layered to the P+ substrate to form another electrode for the device. In addition, connector terminals 29, 31 can be attached to the diode 10, as is commonly understood by those having ordinary skill in the art.

The procedures for masking, etching, implanting and layering are all commonly known to those skilled in the art. The present invention uses blanket implantation to reduce electrical field crowding at the edge or corner to reduce leakage current. The present invention can be used in low voltage transient voltage suppressory transient voltage suppression planar structure, as well as other uses.

Simulation Results

The simulation for the present invention was conducted using the following key process conditions:

Drive-in: 1100° C., 2 hr

Implant:

For blanket implant:
1st: 80 KeV 1e15 Arsenic (blanket implant, w/o mask)
2nd: 80 KeV 1e16 Arsenic (Main Implant, w/mask)

For Junction-Termination-Extension:
1st: 80 KeV 5e15 Arsenic (JTE implant, w/mask)
2nd: 80 KeV 1e16 Arsenic (Main implant, w/mask)

For no modification:
1st: 80 KeV 1e16 Arsenic (Main implant, w/mask)

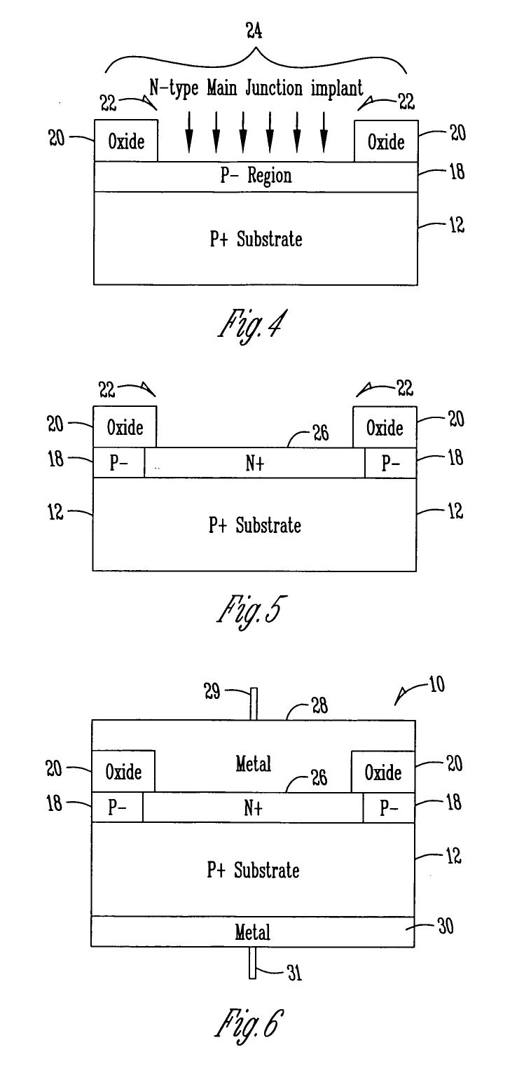

The simulated results of the blanket implant device showing the N+ region depth from 0.5 μm to 1 μm is shown in FIG. 7. FIG. 8 shows the simulated electrical field versus X axis for the blanket implant device.

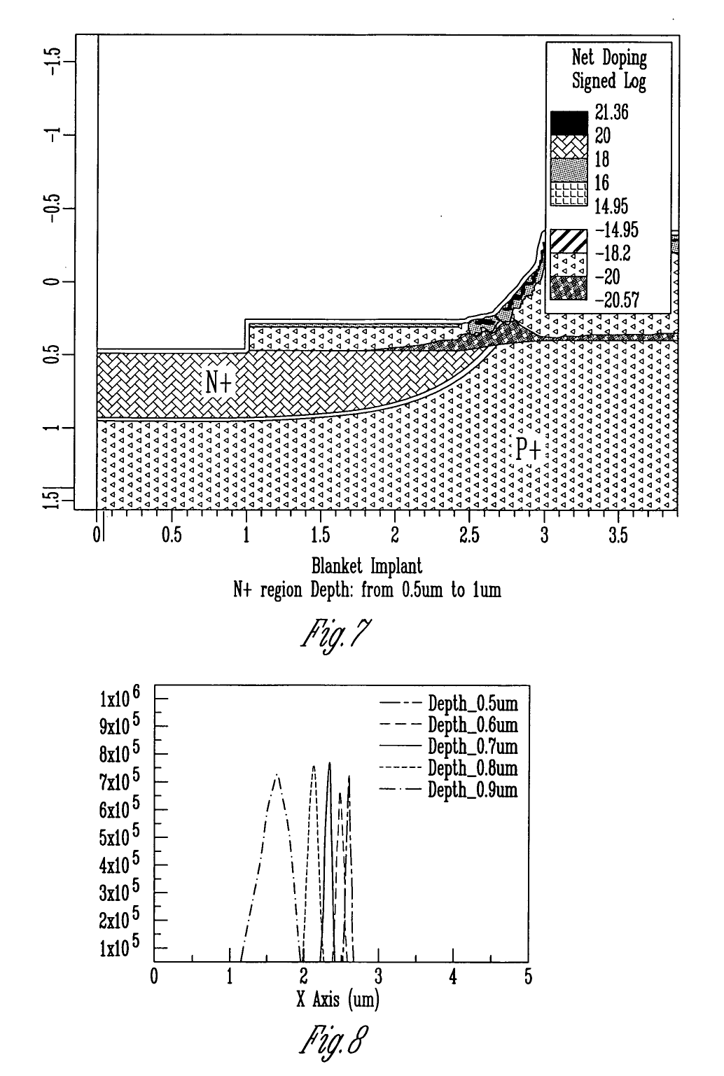

FIG. 9 shows the simulated results for the junction termination extension (JTE) structure with an N+ region depth from 0.9 μm to 1.5 μm. FIG. 10 shows simulated results of the electrical field versus X axis for the junction termination extension structure.

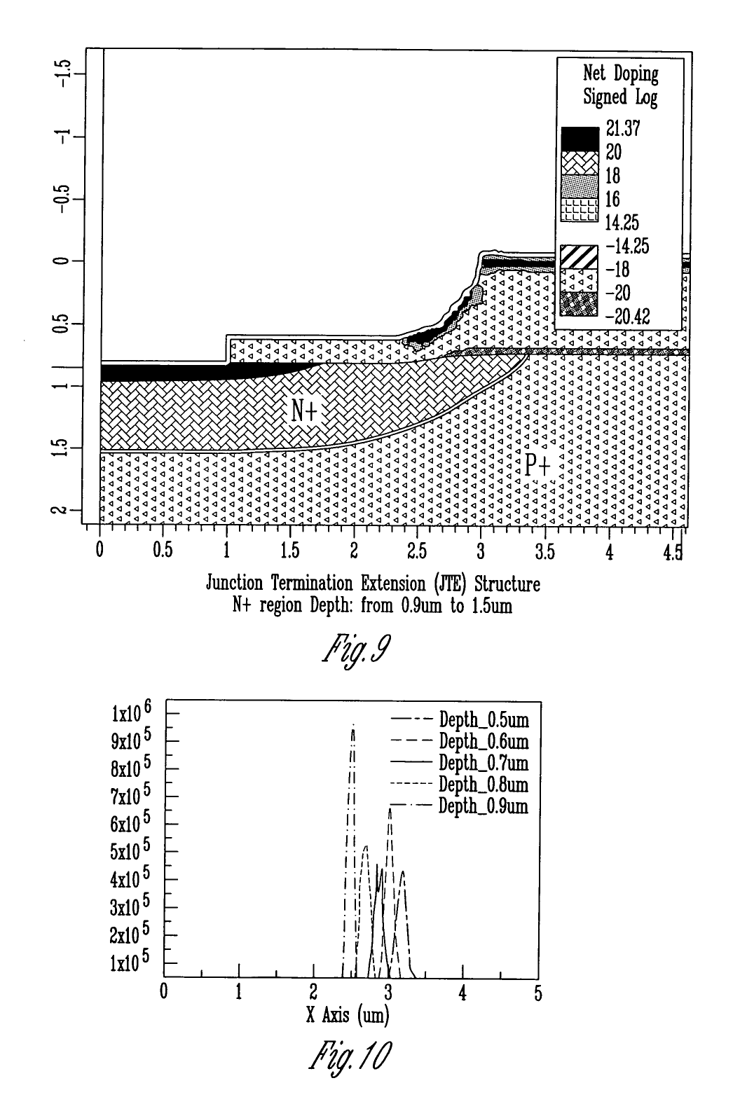

FIG. 11 shows the simulated results for a device with no modification and an N+ region depth from 0.5 μm to 1 μm. FIG. 12 shows the simulated results of the electrical field versus X axis for a device with no modification.

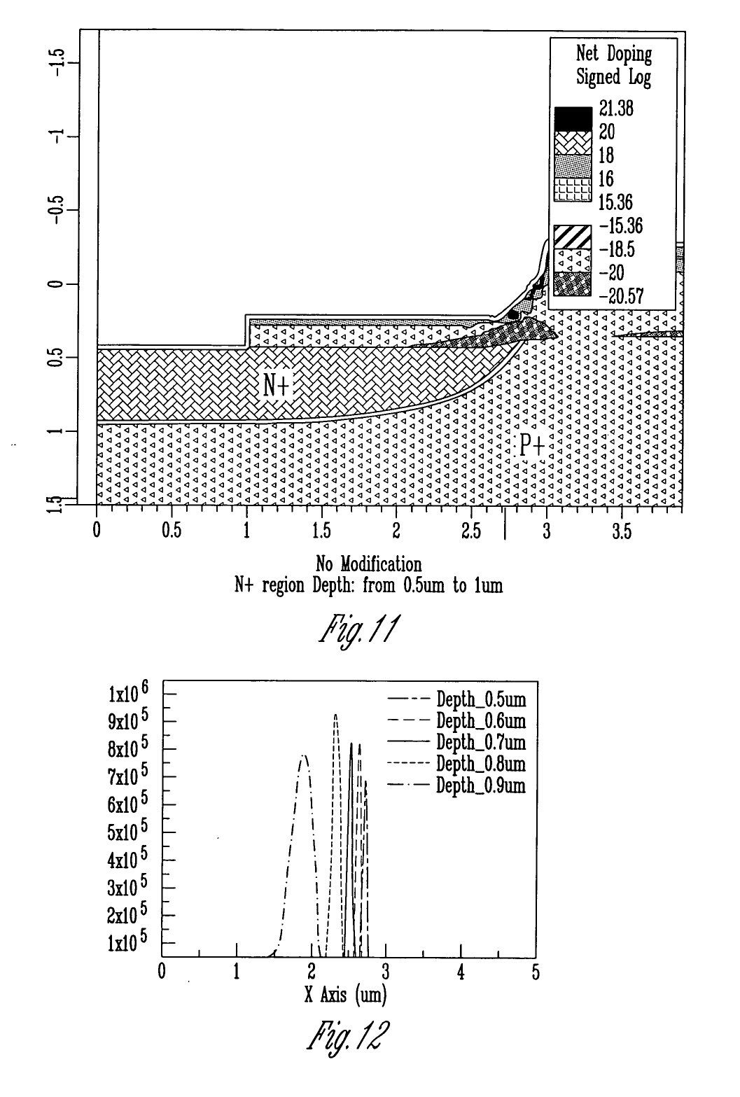

FIG. 13 is a table showing the peak electrical field at the main junction under 3.5V bias. This shows that the peak e-field at the main junction of the three type structures, blanket, JTC, and no modification, are very close to one another.

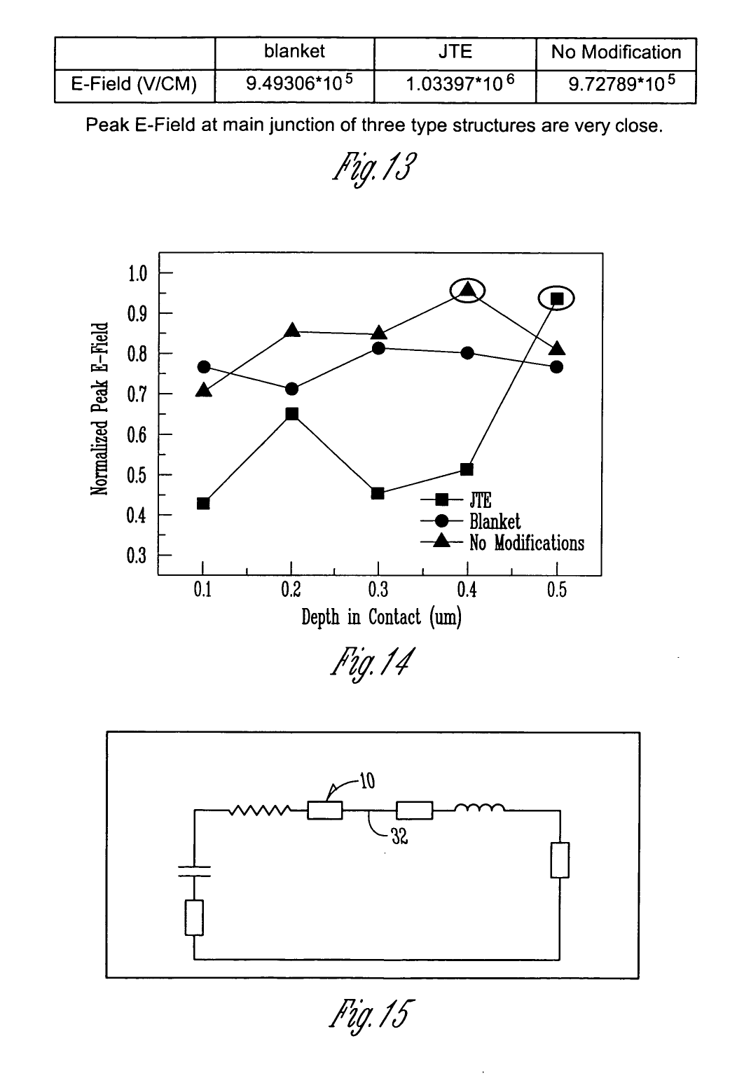

FIG. 14 shows simulated results of the edge electrical field versus the depth under 3.5V bias. This is simulated at a normalized to peak main junction e-field. Without any modification, the peak electrical field is very close to the peak value of the main junction. The JTE structure peak electrical field near the metal contact is effectively suppressed. However, there is still a large electrical field region at the edge. On the other hand, with the blanket implant of the current invention, the edge electrical field is suppressed. There is no large electrical field region at the edge and there is no extra mask required for creating this structure.

Using blanket implantation to reduce the corner electrical field versus junction-termination extension, JTE, structure simplifies the manufacturing process by one mask procedure, which in turn, reduces cycle time and cost. The present invention can be used with fine implantation dosage and energy control. Additionally, the present invention can be used with all transient voltage suppression and diode applications.

The invention has been shown and described above with the preferred embodiments, and it is understood that many modifications, substitutions, and additions may be made which are within the intended spirit and scope of the invention. From the foregoing, it can be seen that the present invention accomplishes at least all of its stated objectives.

What is claimed is:

1. A blanket implanted diode comprising:
a P+ substrate implanted with an N-type dopant blanket implant near a top surface of the substrate creating a P− region;
an oxide mask layered adjacent to and above the P− region, the oxide mask partially etched away from a portion of the P− region creating an etched region;
an N-type main junction implant implanted into the etched region creating an N+ region above the P+ substrate and adjacent the P− region; and
a metal layered above the oxide mask and the etched region.

2. The blanket implanted diode of claim 1 configured as a surface mount or a through hole mount device.

3. The blanket implanted diode of claim 1 constructed with a single masking.

4. The blanket implanted diode of claim 1 wherein doping concentration of the P+ substrate is reduced near the top surface of the substrate.

5. The blanket implanted diode of claim 1 wherein the dopant blanket reduces corner electrical e-field of P-N junction.

6. The blanket implanted diode of claim 1 which causes electrical field crowding near the etched region.

7. The blanket implanted diode of claim 1 wherein the substrate is 0.001˜0.1 Ω-CM boron doped wafer.

8. The blanket implanted diode of claim 1 wherein the N-type dopant blanket implant is arsenic.

9. The blanket implanted diode of claim 1 wherein the oxide mask is a wet oxide mask.

10. The blanket implanted diode of claim 1 wherein the N-type main junction implant is arsenic.

11. The blanket implanted diode of claim 1 further comprising a metal electrode adjacent the substrate, opposite the metal electrode layered above the oxide mask and etched region.

12. The blanket implanted diode of claim 1 wherein the substrate is doped with boron.

13. A method of creating a diode comprising:
implanting an N-type dopant blanket implant near a top surface of a P+ substrate, creating a P− region;
layering an oxide mask adjacent to and above the P− region;
etching away a portion of the mask, creating an etched region;
implanting an N-type main junction implant into the P− region of the etched region creating an N+ region above the P+ substrate and adjacent the P− region; and
layering a metal above the oxide mask and the etched region to thereby provide for manufacturing the diode in a one-mask process.

14. The method of claim 13 wherein the implanting an N-type dopant blanket implant is undergone at about 80 Kev, 1·10¹²˜1·10¹⁵ cm⁻².

15. The method of claim 13 wherein the implanting an N-type main junction implant is undergone at about 80 Kev, 1·10¹⁵˜1·10¹⁷ cm⁻².

16. The method of claim 13 wherein the implanting an N-type dopant blanket implant is with arsenic.

17. The method of claim 13 wherein the implanting an N-type main junction implant is with arsenic.

18. The method of claim 13 further comprising layering a metal below the substrate.

19. The method of claim 13 further comprising packaging the diode for use in an electric circuit.

20. The method of claim 13 further comprising implanting the substrate with Boron to create the P+ substrate.

21. A transient voltage suppression device comprising:
a P+ substrate implanted with an N-type dopant blanket implant near a top surface of the substrate creating a P− region;
an oxide mask layered adjacent to and above the P− region, the oxide mask partially etched away from a portion of the P− region creating an etched region;
an N-type main junction implant implanted into the etched region creating an N+ region above the P+ substrate and adjacent the P− region;
a metal layered above the oxide mask and the etched region;
a connector termination electrically connected to the metal; and
a connector termination electrically connected to the substrate, thereby creating a voltage suppression device with a reduced corner electrical e-field.

22. The transient voltage suppression device of claim 21 wherein the substrate is 0.001˜0.1 Ω-CM boron doped wafer.

23. The transient voltage suppression device of claim 21 wherein the substrate is 0.001˜0.1 Ω-CM boron doped wafer.

24. The transient voltage suppression device of claim 21 wherein the N-type main junction implant is arsenic.

25. The transient voltage suppression device of claim 21 wherein the substrate is doped with boron.

26. A method of transient voltage suppression comprising:
electrically connecting a first connector termination of a voltage suppressing device to an electrical circuit between a first point in the electrical circuit where transient voltage is possible, the voltage suppressing device having a P+ substrate implanted with an N-type dopant blanket implant near a top surface of the substrate creating a P− region, an oxide mask layered adjacent to and above the P− region, the oxide mask partially etched away from a portion of the P− region creating an etched region, an N-type main junction implant implanted into the etched region creating an N+ region above the P+ substrate and adjacent the P− region, a metal layered above the oxide mask and the etched region, the first connector termination electrically connected to the metal, and a second connector termination electrically connected to the substrate; and
electrically connecting the second connector termination to a second point in the electrical circuit where transient voltage is possible.

27. The method of claim 26 wherein both electrically connecting steps are performed with surface mount devices.
